(19) United States
(12) Patent Application Publication
(10) Pub. No.: US 2006/0289958 A1
(43) Pub. Date: Dec. 28, 2006

(54) Color filter and image pickup apparatus including the same

(76) Inventor: Toru Sasaki, Utsunomiya-shi (JP)

Correspondence Address: MORGAN & FINNEGAN, L.L.P., 3 WORLD FINANCIAL CENTER, NEW YORK, NY, 10281-2101, US

(21) Appl. No.: 11/474,005

(22) Filed: Jun. 23, 2006

(30) Foreign Application Priority Data
Jun. 23, 2005 (JP) 2005-182866

(51) Int. Cl. G02B 5/22; H01L 31/00

(52) U.S. Cl. 257/440; 359/891

(57) ABSTRACT

Provided is a color filter, including a plurality of filter units arranged at predetermined intervals, in which each of filter units includes a red transmission filter for red light transmission, a first green transmission filter for first green light transmission, a second green transmission filter for second green light transmission whose spectral characteristic is different from a spectral characteristic of the first green transmission filter, and a blue transmission filter for blue light transmission. In this case, each of the first green transmission filter and the second green transmission filter includes a spectral transmittance distribution in which a correlation value with a function g(λ) of “r”, “g” and “b” color matching functions is equal to or larger than 70%.

### BACKGROUND OF THE INVENTION

1. Field of the Invention

The present invention relates to a color filter suitable to obtain color image information and image pickup apparatus including the color filter.

2. Related Background Art

An image sensor (image pickup device) in which the number of pixels thereof exceeds ten million has been under development, so that the resolution performance of a digital camera using the image sensor is being equivalent to the resolution performance of a silver-halide photography. However, there are still many problems to be solved in view of total image quality based on color reproducibility, the presence of color Moire fringes, and the like.

In particular, in fields with respect to images which require high color reproducibility (for example, medical images to be acquired, product catalog images for Internet transaction, simulator images for the real world), it is desirable to further improve the image quality of a color image.

In a color image pickup device of a single-plate type which is used for an image pickup apparatus whose color reproducibility is improved, the number of colors of a color filter is increased to realize high color reproducibility and real time image pickup. Up to now, there has been known an image pickup apparatus which includes an image pickup device to which a color filter having a transmission wavelength band corresponding to a color between blue and green relative to three primary colors of RGB is added (each of U.S. Application Publication No. US-2003-0160881 and EP 1487219 A1). There has been known an image pickup apparatus using a color filter in which a green filter whose transmission wavelength band is shifted to a long-wavelength side or a short-wavelength side is used for fourth color (Japanese Patent Application Laid-open No. 2004-228662).

The image pickup apparatus for color image formation as described in each of U.S. Application Publication No. US-2003-0160881 and EP 1487219 A1 includes a filter in which a wavelength band having a peak between blue and green (wavelength band of approximately 440 nm to 540 nm) is used as a transmission wavelength band of a fourth filter after the R, G, and B filters. In order to improve the color reproducibility, a transmission wavelength band of each of the image pickup apparatuses is selected such that a wavelength band in which a color matching function “r” of color matching functions “r”, “g”, and “b” takes a negative value transmits through the filter and the correlation with the green filter becomes relatively high. However, when only the fourth filter is used, an extremely high-quality image is not obtained. When the four color filters are arranged based on a Bayer arrangement (color filter arrangement in which four adjacent pixels are composed of RGB three primary colors filters and the number of G filters to be arranged is two times each of the number of R filters and the number of B filters), it is easy to obtain a high-spatial-frequency component, so that a high-quality image is easily obtained. In other words, according to the Bayer arrangement, because the number of green filters to be arranged is two times each of the number of red filters and the number of blue filters, a sampling interval of a green image can be narrowed, with the result that a high spatial frequency can be obtained. However, because of the structure of the color filter described in each of U.S. Application Publication No. US-2003-0160881 and EP 1487219 A1, a maximum transmission wavelength of the fourth color filter and a maximum transmission wavelength of the green filter must be different from each other. Therefore, it is unlikely to improve the correlation with the green filter, so that it is difficult to obtain the high-spatial-frequency component. This problem occurs even in the case of the color filter arrangement described in Japanese Patent Application Laid-open No. 2004-228662.

### SUMMARY OF THE INVENTION

According to the present invention, there is provided a color filter, including a plurality of filter units arranged at predetermined intervals, in which each of filter units includes a red transmission filter for red light transmission, a first green transmission filter for first green light transmission, a second green transmission filter for second green light transmission whose spectral characteristic is different from a spectral characteristic of the first green transmission filter, and a blue transmission filter for blue light transmission. In this case, each of the first green transmission filter and the second green transmission filter includes a spectral transmittance distribution in which a correlation value with a function g(λ) of “r”, “g” and “b” color matching functions is equal to or larger than 70%.

A photoelectric transducer according to the present invention includes an image pickup device disposed on a light exit side of the color filter in addition to the color filter.

An image pickup apparatus according to the present invention includes an optical system for forming an image on the photoelectric transducer in addition to the photoelectric transducer.

### BRIEF DESCRIPTION OF THE DRAWINGS

FIG. 1 is a schematic principal view showing a color filter according to First Embodiment of the present invention;

FIG. 2 is a graph showing examples of shaved filter spectral transmittance distributions of the color filter which can be provided in First Embodiment;

FIG. 3 is an explanatory graph showing “r”, “g” and “b” color matching functions;

FIG. 4 is an explanatory view showing a Bayer arrangement of the color filter according to the present invention;

FIG. 5 is an explanatory graph showing a difference distribution between each shaved filter which can be provided in First Embodiment and a G1 filter;

FIG. 6 is an explanatory graph showing three kinds of filters whose skirt extensions are different from one another, each of which has a maximum value in a wavelength of 515 nm, which are used as comparative objects for an shaved filter which can be provided in First Embodiment;

FIG. 7 is an explanatory graph showing a correlation value between each example of the shaved filter which can be provided in First Embodiment and the G1 filter and a correlation value between each comparison spectral filter and the G1 filter;

FIG. 8 is a graph showing difference correlation values obtained with respect to each shaved filter which can be provided in First Embodiment and the G1 filter containing an error;

FIG. 9 is an explanatory graph showing a centroid wavelength difference between each shaved filter which can be provided in First Embodiment and the G1 filter;

FIG. 10 is a graph showing a difference correlation value of a comparison filter 3;

FIG. 11 is an explanatory diagram showing a processing flow of a color image pickup apparatus which can be provided in First Embodiment;

FIG. 12 is a graph showing an example of a spectral transmittance distribution of a shift filter which can be provided in Second Embodiment;

FIG. 13 is an explanatory graph showing a correlation value between each example of the shift filter which can be provided in Second Embodiment and the G1 filter;

FIGS. 14A and 14B are explanatory graphs showing a difference distribution between each shift filter which can be provided in Second Embodiment and the G1 filter;

FIG. 15 is an explanatory view showing an example of a color filter arrangement including a color filter which can be provided in Second Embodiment; and

FIG. 16 is a schematic view showing an image pickup apparatus according to the present invention.

### DESCRIPTION OF THE PREFERRED EMBODIMENTS

An object of the present invention is to provide a color filter in which an output with respect to a wavelength band where a color matching function “r” of color matching functions “r”, “g”, and “b” takes a negative value can be easily obtained and in which a high-frequency component is easily obtained to acquire an image having preferable color reproducibility and an image pickup apparatus using the color filter.

### First Embodiment

A color filter according to First Embodiment of the present invention and a color image pickup apparatus including the color filter will be described.

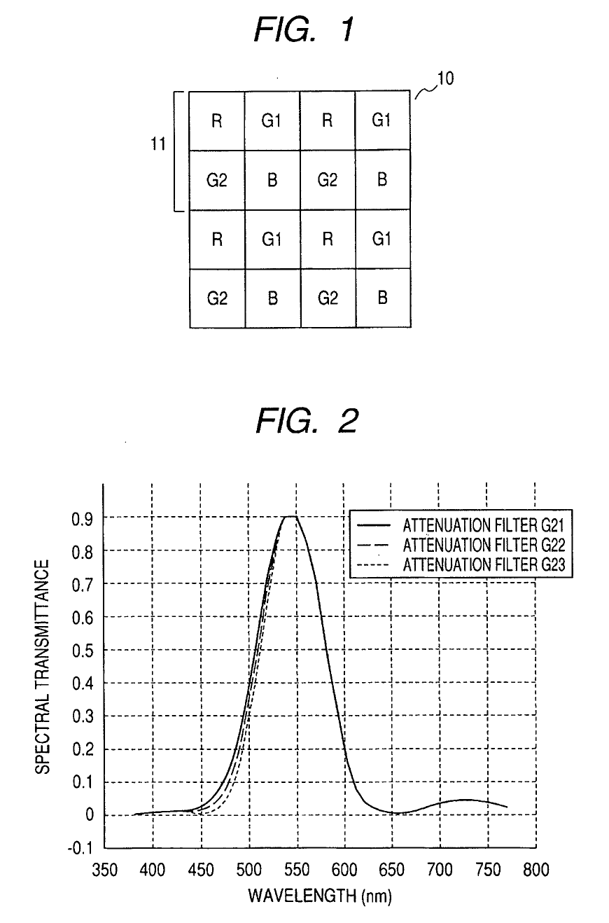

FIG. 1 is a schematic principal view showing the color filter according to the present invention.

In FIG. 1, reference numeral 10 denotes a color filter.

The color filter 10 includes a plurality of filter groups (filter units) 11 which are two-dimensionally arranged at predetermined intervals (certain intervals). Each of the filter groups (filter units) includes a red light transmitting R filter R having a centroid wavelength of 580 nm or more, a first green light transmitting G1 filter G1, a second green light transmitting G2 filter G2 whose spectral characteristic is different from that of the first green light transmission G1 filter G1, and a blue light transmitting B filter B having a centroid wavelength of 480 nm or less. Each of the first green light transmitting G1 filter G1 and the second green light transmitting G2 filter G2 transmits green light whose centroid wavelength is within a range of 480 nm (preferably 500 nm) to 580 nm (preferably 560 nm). Each of the filter groups (filter units) does not necessarily include a plurality of filters and thus may be constructed to include only a single filter having a region whose wavelength band for light transmission is different from one another. The arrangement used in this embodiment is a Bayer arrangement. Note that, in any embodiment, the arrangement of the four color filters is not limited to the Bayer arrangement and thus may be another arrangement.

In the case of each of the G1 filter G1 and the G2 filter G2, a correlation value between a spectral distribution and a function g(λ) of the “r”, “g” and “b” color matching functions is equal to or larger than 70%.

Image pickup elements are disposed corresponding to the respective filters R, G1, G2, and B on a light exit side of the color filter 10 and composes a photoelectric transducer.

Next, terms used to show a state of a spectral distribution indicating transmittance of the color filter in First Embodiment and a subsequent embodiment will be described.

Each of a spectral transmittance distribution and a spectral sensitivity distribution is expressed based on a function f(λ) of a wavelength λ. A correlation value S indicating the degree of approximation of two spectral sensitivity distributions f(λ) and h(λ) is defined using the following expression.

$$\begin{matrix}( Expression 1 ) & \\ S ( \% ) = \frac{\vert {\int }_{λ min}^{λ max} f ( λ ) h ( λ ) ⅆ λ \vert}{{( {\int }_{λ min}^{λ max} {f ( λ )}^{2} ⅆ λ {\int }_{λ min}^{λ max} {h ( λ )}^{2} ⅆ λ )}^{0.5}} \times 100 & ( 1 )\end{matrix}$$

where λ min and λ max denote a lower limit value of a wavelength integration interval and an upper limit value thereof, respectively. In a normal case, the integration is performed in the entire visible light range of λ min (approximately 350 nm) to λ max (approximately 800 nm).

When the two spectral sensitivity distributions f(λ) and h(λ) are completely identical to each other, the correlation value S becomes 100%.

A relationship between the correlation value S and estimation precision will be described. The estimation precision corresponds to precision in the case where a received-light value of a light receiving means which is based on the spectral sensitivity distribution h(λ) is estimated from a received-light value of a light receiving means which is based on the spectral sensitivity distribution f(λ). When each of the received-light values based on the spectral sensitivity distributions f(λ) and h(λ) is varied by a unit quality, probabilities P(λ) and P′(λ) in which monochromatic light of the wavelength λ causes respective variations are approximately expressed as follows.

$$\begin{matrix}( Expression 2 ) & \\ P ( λ ) = \frac{f ( λ )}{{( {\int }_{λ min}^{λ max} {f ( λ )}^{2} ⅆ λ )}^{0.5}} , \\ {P}^{′} ( λ ) = \frac{h ( λ )}{{( {\int }_{λ min}^{λ max} {h ( λ )}^{2} ⅆ λ )}^{0.5}} & ( 2 )\end{matrix}$$

The reason why the probabilities are approximately expressed is that each of the spectral sensitivity distributions f(λ) and h(λ) includes a negative value. Each of f(λ) and h(λ) is strictly a function normalized based on a length and thus different from the probability. However, f(λ) and h(λ) may be treated the same as the probabilities in view of the influence of the negative value. The probability in which the received-light value based on the spectral sensitivity distribution h(λ) is varied by a unit quality by the cause of the monochromatic light of the wavelength λ at the time when the received-light value based on the spectral sensitivity distribution f(λ) is varied by a unit quality is P(λ)P′ (λ). Therefore, a probability P″ in which the received-light value based on the spectral sensitivity distribution h(λ) is varied by the unit quality at the time when the received-light value based on the spectral sensitivity distribution f(λ) is varied by the unit quality (that is, estimation precision of the received-light value based on the spectral sensitivity distribution h(λ)) is expressed by the following expression (3).

$$\begin{matrix}( Expression 3 ) & \\ {P}^{″} = {\int }_{λ min}^{λ max} P ( λ ) {P}^{′} ( λ ) ⅆ λ \frac{{\int }_{λ min}^{λ max} f ( λ ) h ( λ ) ⅆ λ}{{( {\int }_{λ min}^{λ max} {f ( λ )}^{2} ⅆ λ {\int }_{λ min}^{λ max} {h ( λ )}^{2} ⅆ λ )}^{0.5}} & ( 3 )\end{matrix}$$

As a result, it is apparent that an absolute value of estimation precision of the received-light value based on the spectral sensitivity distribution h(λ) of a filter is proportional to the correlation value S obtained by the expression (1).

Next, a centroid wavelength W of the spectral sensitivity distribution f(λ) is defined as follows.

$$\begin{matrix}( Expression 4 ) & \\ W = \frac{{\int }_{λ min}^{λ max} λ \vert f ( λ ) \vert ⅆ λ}{{\int }_{λ min}^{λ max} \vert f ( λ ) \vert ⅆ λ} & ( 4 )\end{matrix}$$

When the spectral sensitivity distribution f(λ) is symmetric with respect to a peak wavelength λp, the centroid wavelength W becomes the peak wavelength λp. When the distribution is biased in one of right and left directions, the centroid wavelength W is shifted in the direction in which bias is large.

As shown in FIG. 2, the G2 filter in this embodiment (hereinafter also referred to as the shaved filter G2) has a spectral transmittance distribution in which an inclination of an attenuation curve located on a short-wavelength side of a spectral transmittance distribution related to a G filter which is one of RGB three primary color filters is increased. In the case of the G1 filter, the correlation value between the spectral transmittance distribution and the function g(λ) of the “r”, “g” and “b” color matching functions may be equal to or larger than 70% and thus the spectral transmittance distribution is similar to the function g(λ). Assume that a shape of the spectral transmittance distribution of the G2 filter which is one of the two green light transmitting filters, the G1 filter and the G2 filter, which are used to explain the color filter according to the present invention satisfies either one of the following features.

(a) The correlation value S between the spectral transmittance distribution of the G2 filter and the color matching function g(λ) (described later) is equal to or larger than 95%.

(b) The correlation value S between a spectral distribution obtained by adding a spectral sensitivity distribution of an image sensor (image pickup device) of an image pickup apparatus using the color filter to the spectral transmittance distribution of the G2 filter and the color matching function g(λ) is equal to or larger than 95%.

Hereinafter, the correlation value S with the G2 filter is calculated to exhibit the feature of the color filter according to First Embodiment of the present invention. From the above-mentioned features, all results obtained by calculation are also applied to the correlation value S with the color matching function g(λ).

The shaved filter G2 is designed to achieve the following two purposes. The first purpose is to obtain outputs (spectral characteristics) close to output values based on the “r”, “g” and “b” color matching functions (spectral characteristics of response of a human eye). The “r”, “g” and “b” color matching functions correspond to three spectral sensitivity distributions r(λ), g(λ), and b(λ) as shown in FIG. 3 and exhibit responses (tristimulus values) of a human eye to light beams whose wavelengths are different from one another. When three color filters (R filter, G filter, and B filter) are used, a response is not obtained from a negative region 102 of the color matching function “r”. Therefore, a fourth filter (corresponding to the shaved filter G2 in this embodiment) is necessary.

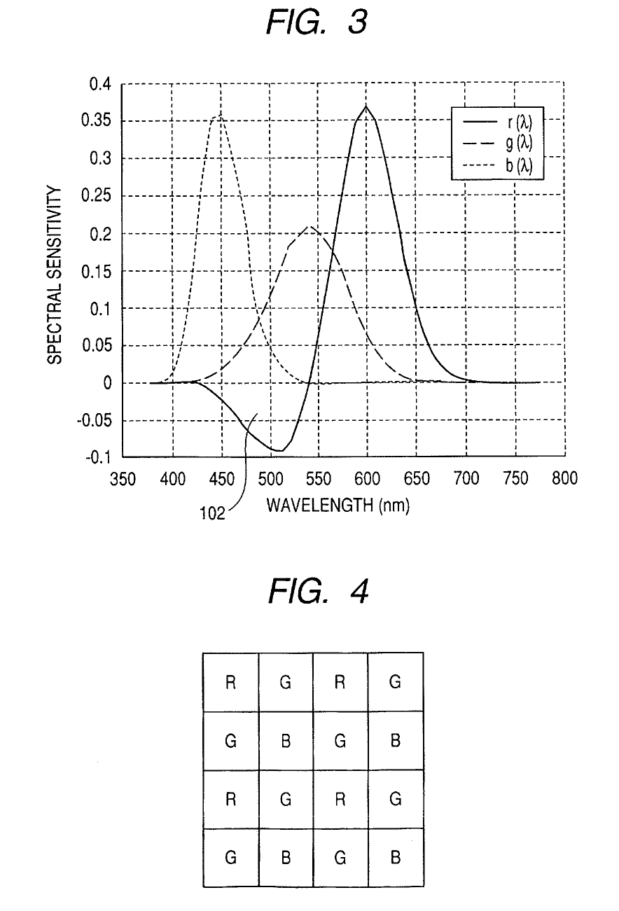

The second purpose is to improve estimation precision of an output value from the G1 filter having a characteristic substantially identical to the color matching function g(λ) in a pixel in which the shaved filter G2 is disposed. The color filters “R”, “G”, and “B” of three primary colors of RGB are normally mounted on the surface of the image pickup device in an arrangement which is called a Bayer arrangement shown in FIG. 4. As shown in FIG. 4, in the Bayer arrangement, the G filters “G” are arranged such that the number of G filters “G” is two times each of the number of R filters “R” and the number of B filters “B”. The number of points obtained using the G filters “G” is set to two times the number of points obtained using other color filters, thereby obtaining a high-spatial-frequency component. When the fourth filter is introduced to achieve the first purpose, it is important to improve the estimation precision of the output value of the G filter so as to be able to obtain the high-spatial-frequency component as in the case of the Bayer arrangement.

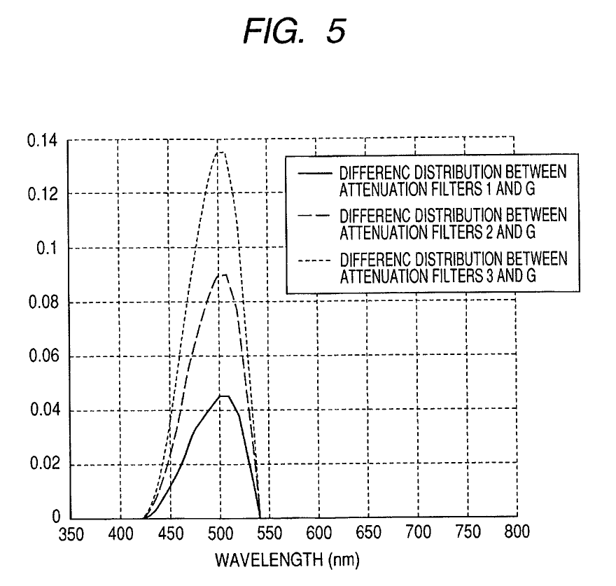

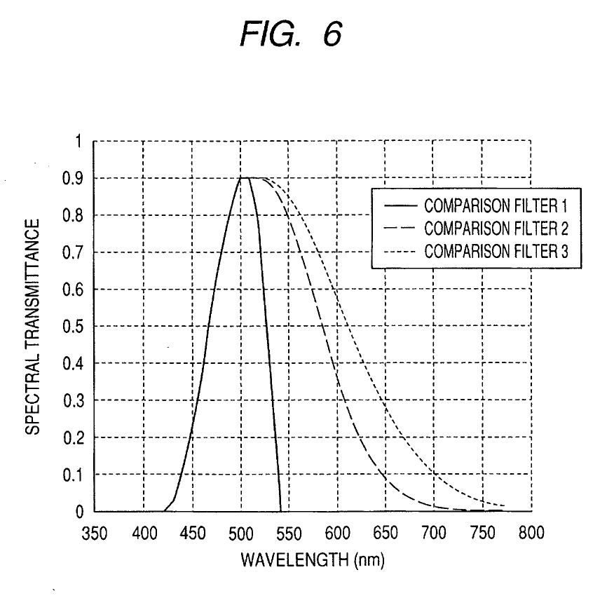

FIG. 2 shows examples of spectral transmittances of three shaved filters G21, G22, and G23, each of which corresponds to the shaved filter G2. The spectral transmittances of the respective shaved filters G21, G22, and G23 are obtained by increasing, at different rates, an inclination on the short-wavelength side of the spectral transmittance of the G1 filter having the spectral characteristic substantially identical to the color matching function g(λ). The example of each of the shaved filters G21, G22, and G23 is characterized by a spectral transmittance distribution difference between each of the shaved filters G21, G22, and G23 and the G1 filter (FIG. 5). A frequency band in which the difference takes a value is substantially identical to a frequency band (wavelength region) in which the color matching function “r” shown in FIG. 3 takes a negative value (hereinafter referred to as the negative region 102). Therefore, the difference distribution significantly correlates with the negative region 102. Thus, when an output value difference between each of the shaved filters G21, G22, and G23 and the G1 filter is calculated (see FIG. 5), it is possible to obtain an approximate value of the output value corresponding to the negative region 102.

To be specific, in the case of the G1 filter and the shaved filter G2, a correlation value between a difference distribution between the spectral transmittance distribution of the G1 filter and the spectral transmittance distribution of the shaved filter G2 and a negative value region in the spectral sensitivity distribution of the function r(λ) of the “r”, “g” and “b” color matching functions is equal to or larger than 80%.

Alternatively, in the case of the shaved filter G2, a correlation value between a difference distribution between the spectral transmittance distribution of the shaved filter G2 and the function g(λ) of the “r”, “g” and “b” color matching functions and the negative value region in the spectral sensitivity distribution of the function r(λ) of the “r”, “g” and “b” color matching functions is equal to or larger than 80%. Therefore, the G2 filter is provided such that a difference between a maximum transmission wavelength thereof and a maximum transmission wavelength of the color matching function “g” of the “r”, “g” and “b” color matching functions becomes smaller.

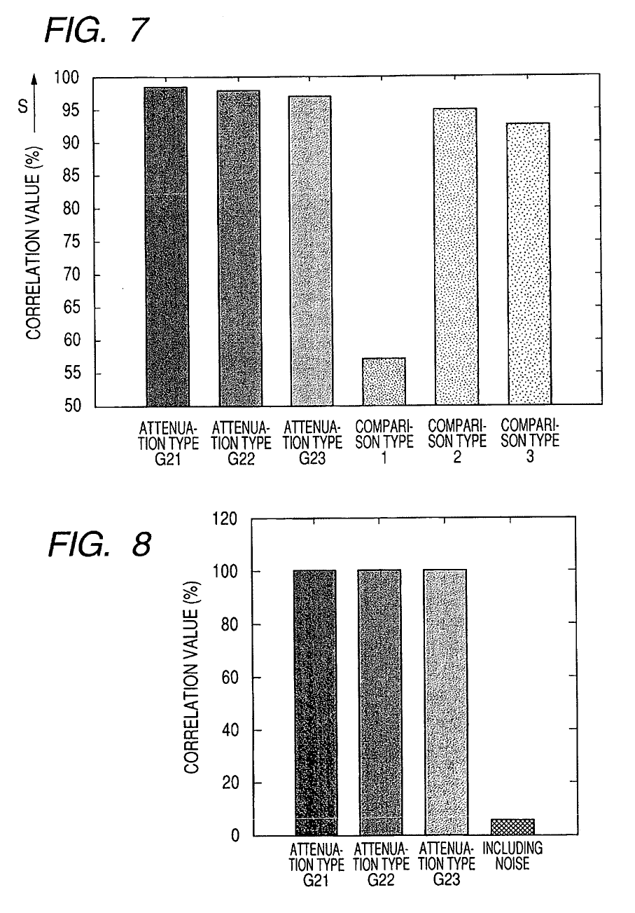

The shaved filters G21, G22, and G23 can be distinguished from a conventional color filter based on the high correlation value with the G1 filter, the characteristic of the difference, and the like. Hereinafter, a numerical difference will be described with reference to examples of the shaved filter G2 and existing spectral filters. FIG. 6 shows an example in which three kinds of filters whose spectral distributions include skirt extensions different from one another, each of which has a maximum value in a wavelength of 515 nm (hereinafter referred to as comparison filters 1 to 3) are comparative objects. The reason why the wavelength associated with the maximum value is set to 515 nm is that this wavelength is associated with the maximum value in a color filter for obtaining an output value of the negative region 102. The skirt extensions of the spectral distributions of the comparison filters 1 to 3 are made only in a long-wavelength direction so as to improve the correlation with the G1 filter. FIG. 7 shows a correlation between each of the examples of the shaved filter G2 and the G1 filter and a correlation between each of the existing comparison filters 1 to 3 and the G1 filter. Each of the examples of the shaved filter G2 exhibits a high correlation value S equal to or larger than 95%. In contrast to this, it is apparent that each of the comparison filters 1 to 3 exhibits a low correlation value S. In particular, the correlation value S of the comparison filter 1 in which the skirt extension of the spectral distribution thereof is narrow becomes approximately 60%, so that sufficient distinction can be made by only the correlation value S.

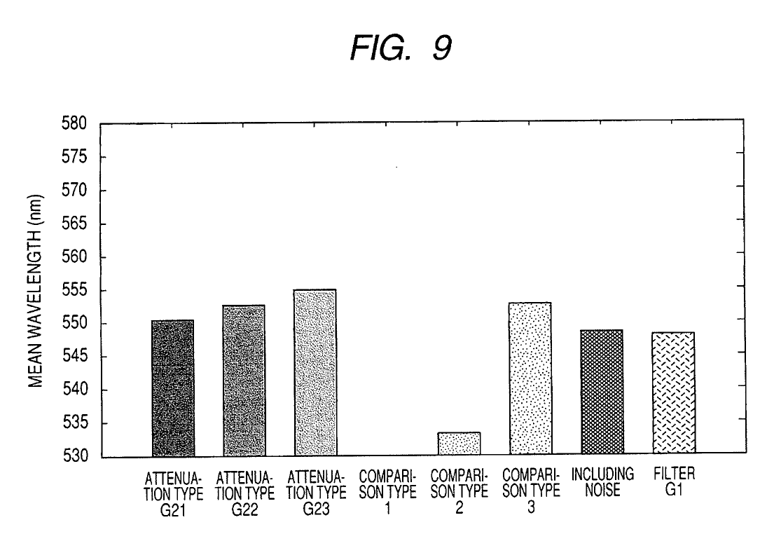

Next, a comparison result based on the centroid wavelength W is shown in FIG. 9. The centroid wavelength of the shaved filter in this embodiment is within a wavelength range of 540 nm to 560 nm or closer to the long-wavelength side than the centroid wavelength (550 nm in wavelength) of the color matching function g(λ). To be specific, the centroid wavelength W of each of the shaved filters G21, G22, and G23 is close to the wavelength of 550 nm as in the case of the G1 filter. On the other hand, the centroid wavelength W of each of the comparison filters 1 to 3 is located extremely on a long-wavelength side, except for the comparison filter 3. Although the comparison filter 2 is a filter in which the skirt of the spectral distribution thereof is extended so as to improve the correlation with the G1 filter, the comparison filter 2 can be clearly distinguished from the G2 filter in this embodiment by the examination of the centroid wavelength.

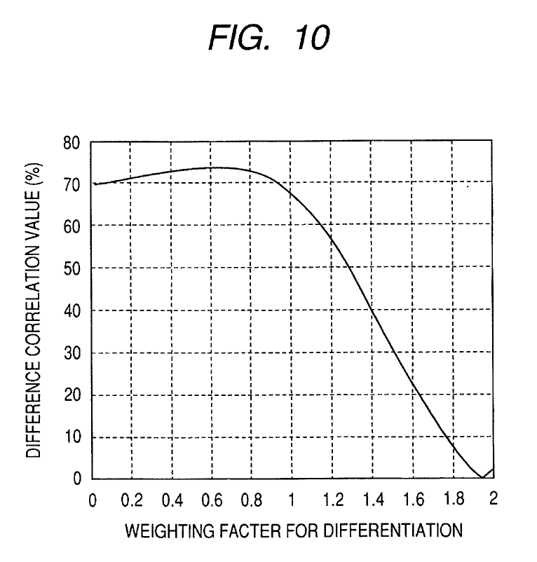

The comparison filter 3 is a filter in which the skirt of the spectral distribution thereof is further significantly extended to obtain the same centroid wavelength W as that of the G1 filter. Therefore, it is difficult to say that the comparison filter 3 is a normal comparative object. However, the filter in this embodiment can be distinguished from such a type of filter. When the filter in this embodiment is distinguished from such a type of filter, the comparison is made based on a difference correlation value with the G1 filter. The difference correlation value is a correlation value between a difference distribution between the target filter (shaved filter G2 or the comparison filter) and the G1 filter and the negative region 102 of the color matching function “r”. The difference between the target filter and the G1 filter is obtained by the subtraction using a weighting factor for the G1 filter. The amount of weighting factor at the time of subtraction is arbitrary and thus it is necessary for the comparison to select the weighting factor so as to obtain a highest difference correlation value. FIG. 10 shows a result obtained by calculation of the difference correlation value according to a changed weighting factor in the case where the comparison filter 3 is set as the target filter. In this case, a maximum value of the difference correlation value is approximately 80% and thus does not become a high value in principle. When the shaved filter is set as the target filter, the difference correlation value becomes substantially 100%, with the result that the distinction is possible. Thus, each of the correlation value S of the shaved filter and the correlation value S of the filter having the maximum value in the wavelength of 515 nm is clearly distinguishable.

Next, an example in which a green filter having a small amount of manufacturing error (hereinafter referred to as an error-contained G filter) is set as a comparative object will be described. A correlation value between the error-contained G filter and the G1 filter becomes a value close to 100%, so it is difficult to distinguish the error-contained G filter from the shaved filter G2 based on the correlation value. Therefore, a difference obtained by comparison based on the difference correlation values will be described. FIG. 8 is a graph showing the difference correlation values obtained with respect to the examples of the shaved filter G2 and the error-contained G filter. An error contained in the error-contained G filter is small and easily distributed uniformly, so the difference correlation value does not become higher than 20%. In contrast to this, the difference correlation value of the shaved filter G2 becomes a value close to 100%. Thus, the shaved filter G2 can be clearly distinguished from the error-contained G filter having a spectral transmittance distribution similar to that of the G1 filter.

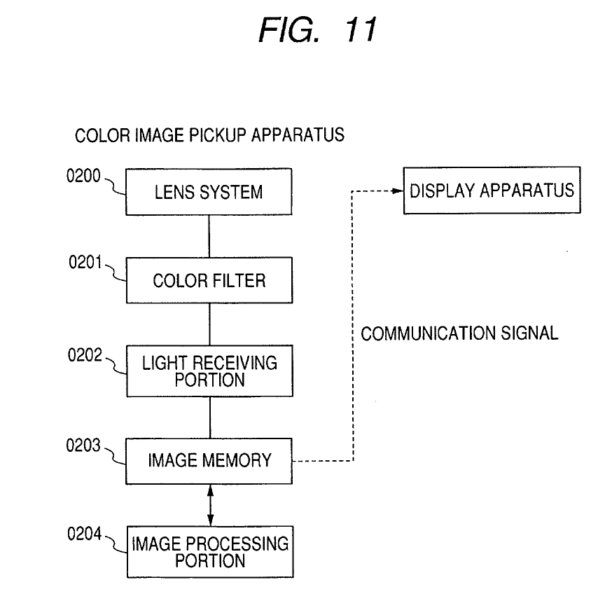

A color image pickup apparatus including the shaved filter G2 will be described. FIG. 11 shows a processing flow (flow chart) of the color image pickup apparatus. In the color image pickup apparatus, an optical image formed by a lens system (image pickup system) 0200 is divided into respective color images using a color filter 0201. An arbitrary method is used as a method of mounting the color filter when the color filter includes the G1-fiter and the shaved filter G2. In this embodiment, a color filter array in which one of the two G filters of the Bayer arrangement shown in FIG. 1 is replaced by the shaved filter G2 is used. In a light receiving portion 0202, a light intensity signal of an optical image passing through the color filter is obtained by an image sensor. A brightness signal stored in an image memory 0203 is subjected to image processings (white balance processing, noise removal, color interpolation processing, and color matrix processing) by an image processing portion 0204.

An output signal of the color image pickup apparatus is transmitted to an arbitrary display device and displayed thereon. In this embodiment, a liquid crystal display in which the number of color filters becomes larger than that in a normal case to widen a color region is used.

As described above, according to this embodiment, it is possible to provide an image pickup apparatus having a photoelectric transducer including the color filter with the G2 filter in which the inclination of the attenuation curve located on the short-wavelength side of the spectral transmittance of the G1 filter is increased. Therefore, the color reproducibility can be improved and a high-frequency component image can be obtained.

### Second Embodiment

A color filter according to Second Embodiment of the present invention and a color image pickup apparatus including the color filter will be described. A G2 filter included in the color filter provided in Second Embodiment (hereinafter referred to as a shift filter) is designed based on the spectral transmittance distribution of a green filter “G” of the RGB three primary color filters as in the case of the G2 filter provided in First Embodiment. A feature of the shift filter is that the inclination of the attenuation curve located on the short-wavelength side of the spectral transmittance distribution becomes larger and the inclination of the attenuation curve located on a high-frequency side becomes smaller, unlike the G1 filter.

To be specific, in the case of the G1 filter and the shift filter (G2 filter), a correlation value between a difference distribution between the spectral transmission distribution of the G1 filter and a spectral transmission distribution of the shift filter and a negative value region in the spectral sensitivity distribution of the function r(λ) of the “r”, “g” and “b” color matching functions is equal to or larger than 80% in a wavelength band of 550 nm or less.

Alternatively, in the case of the shift filter, a correlation value between a difference distribution between the spectral transmittance distribution of the shift filter and the function g(λ) of the “r”, “g” and “b” color matching functions and the negative value region in the spectral sensitivity distribution of the function r(λ) of the “r”, “g” and “b” color matching functions is equal to or larger than 80% in the wavelength band of 550 nm or less.

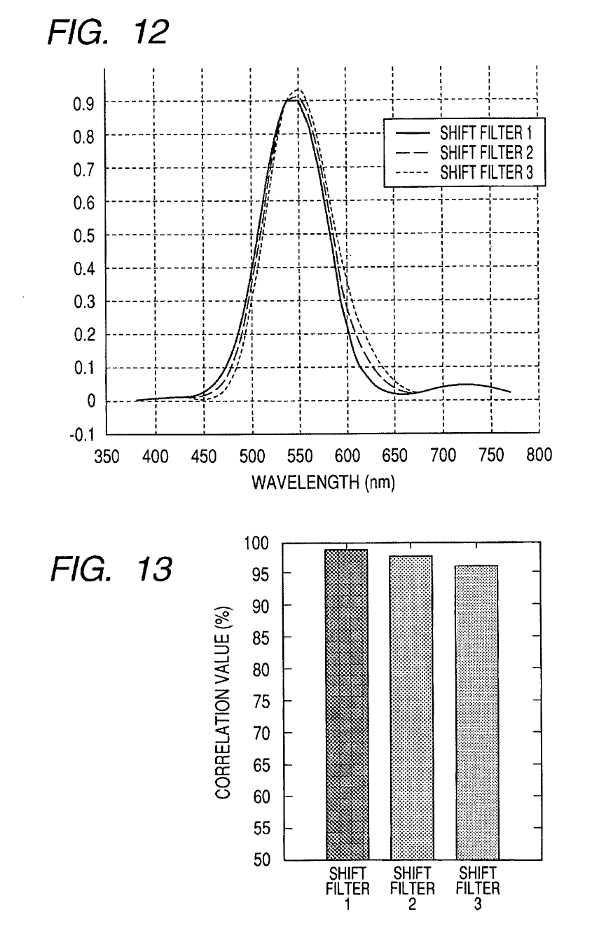

FIG. 12 shows examples of spectral characteristics of shift filters 1 to 3, each of which is the above-mentioned shift filter. Inclinations on the long-wavelength side change in addition to changes in inclinations on the short-wavelength side. FIG. 13 shows a correlation value between each of the shift filters 1 to 3 and the G1 filter. Each correlation value becomes lower than the correlation value of the G2 filter which can be provided in First Embodiment. The reason is that the denominator of the correlation value S expressed by the expression (1) increases because the distribution is extended to the long-wavelength side by the spectral transmittance distribution of the G1 filter. The correlation value S becomes smaller but is still higher than a correlation value between a comparison filter whose transmittance becomes maximum in the wavelength of 515 nm and the G1 filter, which are used for the description in First Embodiment of the present invention (FIG. 6). Therefore, the estimation precision of a green output value can be improved.

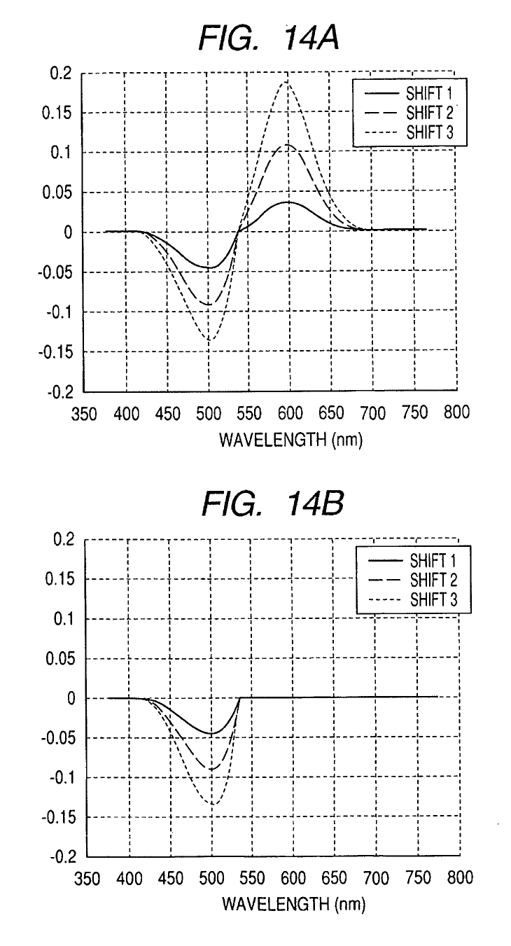

On the other hand, as shown in FIG. 14A, a value of the difference distribution between the spectral distribution of each of the shift filters 1 to 3 and the spectral distribution of the G1 filter becomes high in an attenuation region on the long-wavelength side of the spectral transmittance distribution of the G1 filter. As a result, a correlation value with the negative region 102 of the color matching function “r” significantly reduces. Therefore, when processing is not performed, the precision of a red output value cannot be improved. In order to deal with such a problem, the shift filter is designed such that the correlation value between the difference distribution on the long-wavelength side and the R filter is maintained to be equal to or larger than 90%. When such a design is performed, it is possible to produce a difference distribution (FIG. 14B) by subtracting a weighted distribution of the R filter from the difference distribution of the shift filter as shown in FIG. 14A. An output value in the case where the difference distribution (FIG. 14B) is assumed to be the spectral transmittance is obtained by subtracting a weighted output value of the R filter from an output value difference between the G1 filter and the shift filter. A correlation value between the difference distribution (FIG. 14B) and the negative region of the color matching function “r” is high, with the result that the influence of the negative region of the color matching function “r” can be calculated with high precision.

The advantage of the shift filter is that the transmission wavelength band thereof is wider than the transmission wavelength band of a filter which can be provided in First Embodiment of the present invention. Therefore, light quality efficiency becomes higher, so that it is easy to select a material.

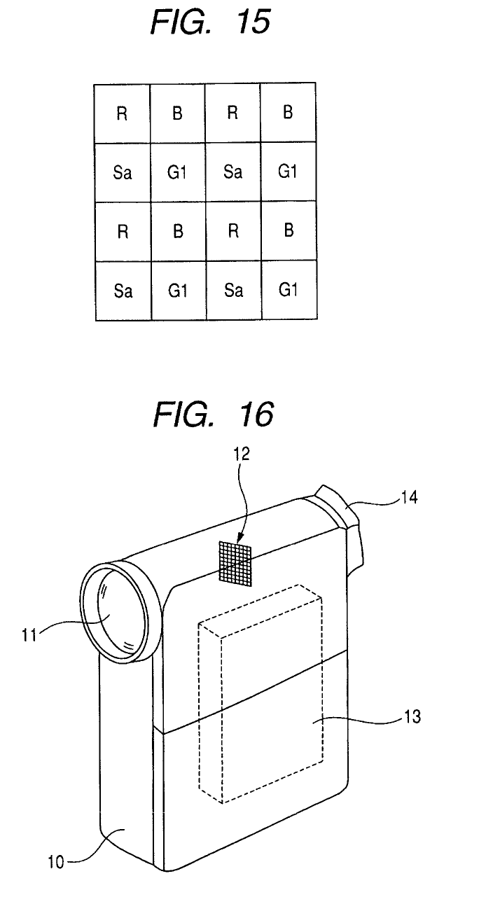

As in the case of First Embodiment, the structure shown in FIG. 11 is used for the color image pickup apparatus including the color filter which can be provided in Second Embodiment. The structure of the color image pickup apparatus is common to that in First Embodiment except for the color filter arrangement. The color filter arrangement is arbitrarily provided such that the G1 filter and the shift filter are located close to each other. In Second Embodiment, as shown in FIG. 15, the R filters and G1 filters are diagonally disposed and the shift filters (expressed by Sa in FIG. 15) and the G1 filters are arranged in a lateral direction. Such an arrangement is effective to maintain high resolution of points in the lateral direction.

As described above, according to Second Embodiment, it is possible to provide an image pickup apparatus including the color filter in which the inclination of the attenuation curve located on the short-wavelength side of the spectral transmittance of the G1 filter is increased and the inclination of the attenuation curve located on the long-wavelength side thereof is reduced. Therefore, the color reproducibility can be improved and a high-frequency component can be obtained.

It is possible to more easily produce a color filter as compared with the color filter which can be provided in First Embodiment.

Next, an example of a video camera using the photoelectric transducer according to the present invention will be described with reference to FIG. 16.

In FIG. 16, the video camera includes a video camera main body 10, a photographing optical system 11, a photoelectric transducer 12 according to the present invention, a memory 13, and a finder 14. The photographing optical system 11 includes a zoom lens. The photoelectric transducer 12 receives a subject image formed by the photographing optical system 11 and includes an image pickup device disposed on a light exit side of a color filter. The memory 13 stores information corresponding to the subject image subjected to photoelectric conversion by the image pickup device 12. The finder 14 is used to observe the subject image displayed on a display device, which is not shown. The display element includes, for example, a liquid crystal panel and the subject image formed on the image pickup device 12 is displayed thereon.

The image pickup apparatus according to this example can be also applied to a digital still camera in the same manner. Therefore, when the photoelectric transducer according to the present invention is applied to an image pickup apparatus such as a video camera or a digital still camera, an image pickup apparatus having preferable color reproducibility can be realized.

According to the embodiments of the present invention, the output value based on the negative spectral sensitivity distribution of the color matching function “r” is obtained. Therefore, it is possible to realize a color filter capable of improving the color reproducibility and minimizing the deterioration of the spatial resolution and an image pickup apparatus including the color filter.

This application claims priority from Japanese Patent Application No. 2005-182866 filed Jun. 23, 2005, which is hereby incorporated by reference herein.

What is claimed is:

1. A color filter, comprising a plurality of filter units,
the filter units each including a red transmission filter for red light transmission, a first green transmission filter for first green light transmission, a second green transmission filter for second green light transmission whose spectral characteristic is different from a spectral characteristic of the first green transmission filter, and a blue transmission filter for blue light transmission,
wherein each of the first green transmission filter and the second green transmission filter includes a spectral transmittance distribution in which a correlation value with a function g(λ) of “r”, “g” and “b” color matching functions is equal to or larger than 70%.

2. A color filter according to claim 1, wherein a correlation value between a difference distribution between the spectral transmittance distribution of the first green transmission filter and the spectral transmittance distribution of the second green transmission filter and a negative value region in a spectral sensitivity distribution of a function r(λ) of the “r”, “g” and “b” color matching functions is equal to or larger than 80%.

3. A color filter according to claim 1, wherein the second green transmission filter has a correlation value between a difference distribution between the spectral transmittance distribution of the second green transmission filter and the function g(λ) of the “r”, “g” and “b” color matching functions and a negative value region in a spectral sensitivity distribution of a function r(λ) of the “r”, “g” and “b” color matching functions, which is equal to or larger than 80%.

4. A color filter according to claim 1, wherein each of the first green transmission filter and the second green transmission filter has a correlation value between a difference distribution between the spectral transmittance distribution of the first green transmission filter and the spectral transmittance distribution of the second green transmission filter and a negative value region in a spectral sensitivity distribution of a function r(λ) of the “r”, “g” and “b” color matching functions, which is equal to or larger than 80% in a wavelength band of 550 nm or less.

5. A color filter according to claim 1, wherein the second green transmission filter has a correlation value between a difference distribution between the spectral transmittance distribution of the second green transmission filter and the function g(λ) of the “r”, “g” and “b” color matching functions and a negative value region in a spectral sensitivity distribution of a function r(λ) of the “r”, “g” and “b” color matching functions, which is equal to or larger than 80% in a wavelength band of 550 nm or less.

6. A color filter according to claim 1, wherein the second green transmission filter has a centroid wavelength of a spectral transmittance which is within a range of 540 nm to 560 nm or closer to a long-wavelength side than a centroid wavelength of a color matching function g.

7. A photoelectric transducer, comprising:
the color filter according to claim 1; and
an image pickup device disposed on a light exit side of the color filter.

8. An image pickup apparatus, comprising:
the photoelectric transducer according to claim 7; and
an optical system for forming an image in the photoelectric transducer.
